(19) United States
(12) Patent Application Publication
(10) Pub. No.: US 2015/0156883 A1
(43) Pub. Date: Jun. 4, 2015

(54) PRINTED CIRCUIT BOARD AND MANUFACTURING METHOD THEREOF

(71) Applicant: SAMSUNG ELECTRO-MECHANICS CO., LTD., Suwon (KR)

(72) Inventors: Kang Wook Bong, Suwon (KR); Jin Won Lee, Suwon (KR); Young Gwan Ko, Suwon (KR)

(73) Assignee: SAMSUNG ELECTRO-MECHANICS CO., LTD., Suwon (KR)

(21) Appl. No.: 14/337,531

(22) Filed: Jul. 22, 2014

(30) Foreign Application Priority Data
Dec. 4, 2013 (KR) 10-2013-0149973

(51) Int. Cl. H05K 1/18; H05K 3/46; H05K 1/11; H05K 1/02

(52) U.S. Cl. CPC H05K 1/184; H05K 1/0298; H05K 3/4644; H05K 1/115; H05K 2201/09545

(57) ABSTRACT

A printed circuit board (PCB) may include: an insulating layer; a first circuit layer including a first circuit pattern embedded therein, such that an upper surface thereof is exposed from a first surface of the insulating layer; and a metal post formed on the first circuit pattern. In the PCB, a fine pitch is implemented by embedding circuit patterns and forming metal posts, and a thickness of the PCB is reduced through a coreless structure.

### CROSS-REFERENCE TO RELATED APPLICATION

This application claims the benefit of Korean Patent Application No. 10-2013-0149973 filed on Dec. 4, 2013, with the Korean Intellectual Property Office, the disclosure of which is incorporated herein by reference.

### BACKGROUND

The present disclosure relates to a printed circuit board and a manufacturing method thereof.

Recent developments within the electronics industry have been trigger by the growing demand for multifunctional, miniaturized electronic components. In line with this, research into the implementation of high density circuit patterns on printed circuit boards (PCBs) on which electronic components are mounted and the development thereof have been in progress.

To meet demand for high density boards, circuit patterns need to be connected to high density between layers. According to a plating technique, a via hole is formed and an inner circumferential surface of the via hole is plated or the via hole is filled with a plating layer to implement interlayer connectivity. However, the aforementioned related art has limitations in terms of high density interlayer connectivity, and thus, the technological process cannot be applied as a complete production technology.

Thus, a structure allowing for the implementation of high density of circuits through forming interlayer connections between circuit patterns to have high density or increasing a degree of freedom in circuit design is required.

Meanwhile, an increase in inputs/outputs (I/O) between a board and an integrated circuit (IC) chip results in a shortage of spaces, and thus, demand for the implementation of fine pitches in bumps has continued, and the implementation of fine pitches through a metal post, a next-generation bumping technique capable of overcoming limitations in terms of the pitches of solder bumps and the reliability thereof, has been proposed.

### RELATED ART DOCUMENT

### (Patent Document 1) Korean Patent Laid-Open Publication No. 2012-0069987

### SUMMARY

An exemplary embodiment in the present disclosure may provide a printed circuit board in which circuit patterns are embedded and a metal post is formed, implementing a fine pitch, and which has a coreless structure having a reduced thickness, and a manufacturing method thereof.

According to an exemplary embodiment in the present disclosure, a printed circuit board (PCB) may include: an insulating layer; a first circuit layer including a first circuit pattern embedded therein, such that an upper surface thereof is exposed from a first surface of the insulating layer; and a metal post formed on the first circuit pattern.

A level of an upper surface of the first circuit pattern may be equal to a level of an upper surface of the insulating layer.

The PCB may include a second circuit layer including a second circuit pattern formed on a second surface of the insulating layer; and a via electrode formed in the insulating layer to electrically connect the first circuit pattern and the second circuit pattern.

The PCB may have a coreless structure.

The PCB may further include a build-up layer stacked on the second surface of the insulating layer.

The PCB may further include a solder resist formed such that circuit patterns for a connection pad of the first circuit layer and the second circuit layer and the metal post are exposed.

The metal post may include a first metal post formed on the first circuit pattern and a second metal post formed on the first metal post and protruded from a surface of the solder resist.

A width of the second metal post may be equal to or less than that of the first metal post.

The metal post may be formed of copper (Cu).

According to an exemplary embodiment in the present disclosure, a method of manufacturing a printed circuit board (PCB) may include: preparing a carrier substrate including a first metal layer formed on at least one surface thereof; forming a photoresist having an opening for forming a second metal post on one surface of the first metal layer and filling the opening to forma second metal post; forming a solder resist on the photoresist such that the second metal post is exposed; forming a first circuit layer including a first metal post and a first circuit pattern on the second metal post; and forming an insulating layer such that the first circuit pattern is embedded therein.

The method may further include: forming a via hole in the insulating layer such that the first circuit pattern is exposed; and filling the via hole to form a via electrode and forming a second circuit layer including a second circuit pattern electrically connected to the first circuit pattern through the via electrode.

The method may further include: separating the first metal layer from the carrier substrate; and removing the first metal layer and the photoresist.

A level of an upper surface of the first circuit pattern may be equal to a level of an upper surface of the insulating layer.

The method may further include: forming a build-up layer on the second circuit layer.

A width of the second metal post may be equal to or less than that of the first metal post.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view illustrating a structure of a printed circuit board (PCB) according to an exemplary embodiment of the present disclosure;

FIG. 2 is a cross-sectional view illustrating a structure of a PCB according to an exemplary embodiment of the present disclosure; and

FIGS. 3 through 17 are views illustrating sequential processes in a method of manufacturing a PCB according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

Printed Circuit Board

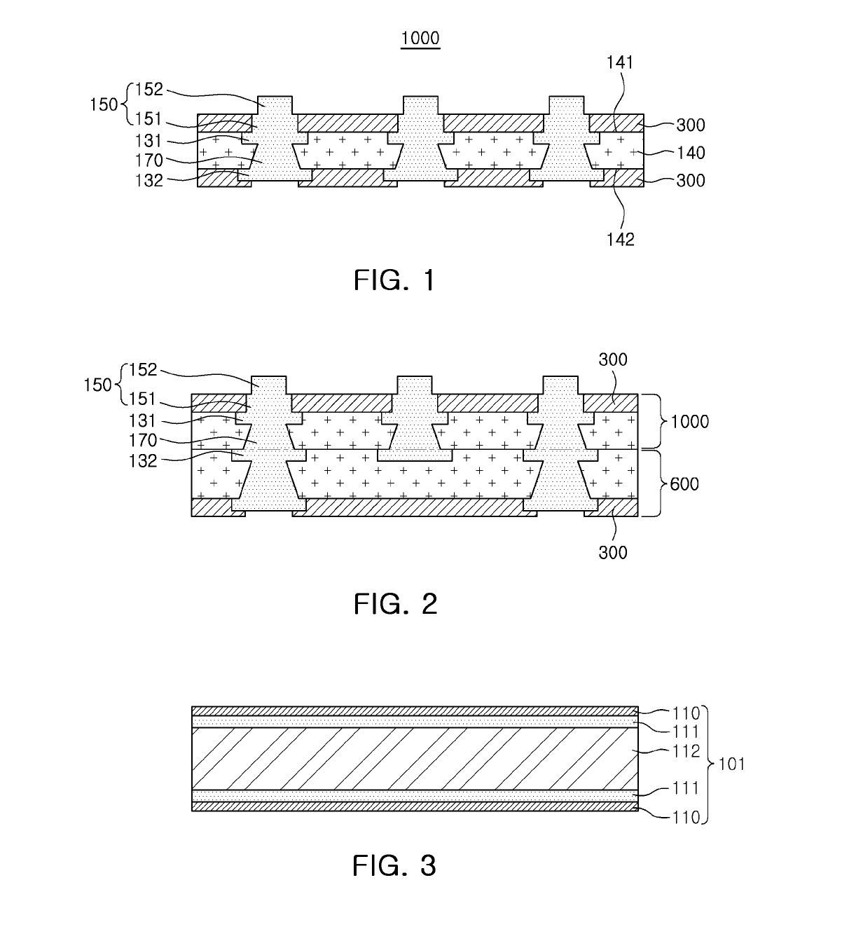

FIGS. 1 and 2 are cross-sectional views illustrating structures of a printed circuit board (PCB) according to an exemplary embodiment of the present disclosure.

Referring to FIG. 1, a PCB 1000 according to an exemplary embodiment of the present disclosure includes an insulating layer 140, a first circuit layer including a first circuit pattern 131 embedded such that a first surface 141 of the insulating layer 140 is exposed, and a metal post 150 formed on the first circuit pattern 131.

A resin insulating layer may be used as the insulating layer 140. The resin insulating layer may be formed of a thermosetting resin such as an epoxy resin, a thermoplastic resin such as polyimide, or a material obtained by impregnating any thereof with a reinforcing material such as glass fiber or an inorganic filler, for example, prepreg. Also, a thermosetting resin and/or a photocurable resin, or the like, may be used as a material for the resin insulating layer but the present disclosure is not limited thereto.

In the circuit board field, any circuit layer may be applied without limitation, as long as the circuit layer is formed of a conductive metal for a circuit, and typically, copper is used in a PCB.

A surface-treated layer (not shown) may be further formed on the exposed circuit layer as needed.

The surface-treated layer may be formed through, for example, a method such as electro-gold plating, immersion gold plating, an organic solderability preservative (OSP) process, immersion tin plating, immersion silver plating, electroless nickel and immersion gold (ENIG) plating, direct immersion gold (DIG) plating, hot air solder leveling (HASL), or the like, but the present disclosure is not limited thereto and any method may be used as long as the method is known in the art.

The first circuit pattern 131 may be embedded such that a level of the exposed upper surface thereof is equal to a level of the insulating layer 140.

A second circuit layer including a second circuit pattern 132 may be formed on a second surface 142 of the insulating layer 140 and include a via electrode 170 electrically connecting the first circuit pattern 131 and the second circuit pattern 132 in the insulating layer 140.

The via electrode 170 may be formed of a material identical to that of the first circuit pattern 131. Typically, copper (Cu) is used, but any material may be applied without limitation, as long as it can be used as a conductive metal.

In the drawing, the via electrode 170 is illustrated as having a tapered shape having a diameter increasing toward a lower surface, but the via electrode may be formed to have any shape known in the art, such as a tapered shape having a diameter decreasing toward the lower surface, a cylindrical shape, or the like.

A solder resist 300 may be formed on a surface of the PCB such that a circuit pattern for a connection pad of the first circuit layer and the second circuit layer and the metal post 150 are exposed.

The metal post 150 may include a first metal post 151 formed on the first circuit pattern 131 and a second metal post 152 formed on the first metal post 151 and protruded from a surface of the solder resist 300.

A width of the second metal post 132 may be equal to or less than that of the first metal post 131.

The metal post 150 may be formed of a material identical to that of the first circuit pattern 131 and the via electrode 170. For example, the metal post 150 may be formed of copper (Cu) but any material may be applied without limitation, as long as it used as a conductive metal.

The PCB 1000 may have fine pitches implemented by forming the metal post 150 on the first circuit pattern 131 embedded therein, and since the PCB 1000 has a coreless structure, the PCB 1000 may be implemented as being thinner.

Referring to FIG. 2, the PCB according to an exemplary embodiment of the present disclosure may further include a build-up layer 600 stacked on the second surface 142 of the insulating layer 140.

In the drawing, the build-up layer 600 stacked on the second surface 142 of the insulating layer 140 is illustrated as a dual-layer including a build-up insulating layer and a build-up circuit layer, but the build-up layer 600 may also be formed as a triple layer or a quadruple layer, or may be formed within the scope utilized by a person skilled in the art.

Method of Manufacturing PCB

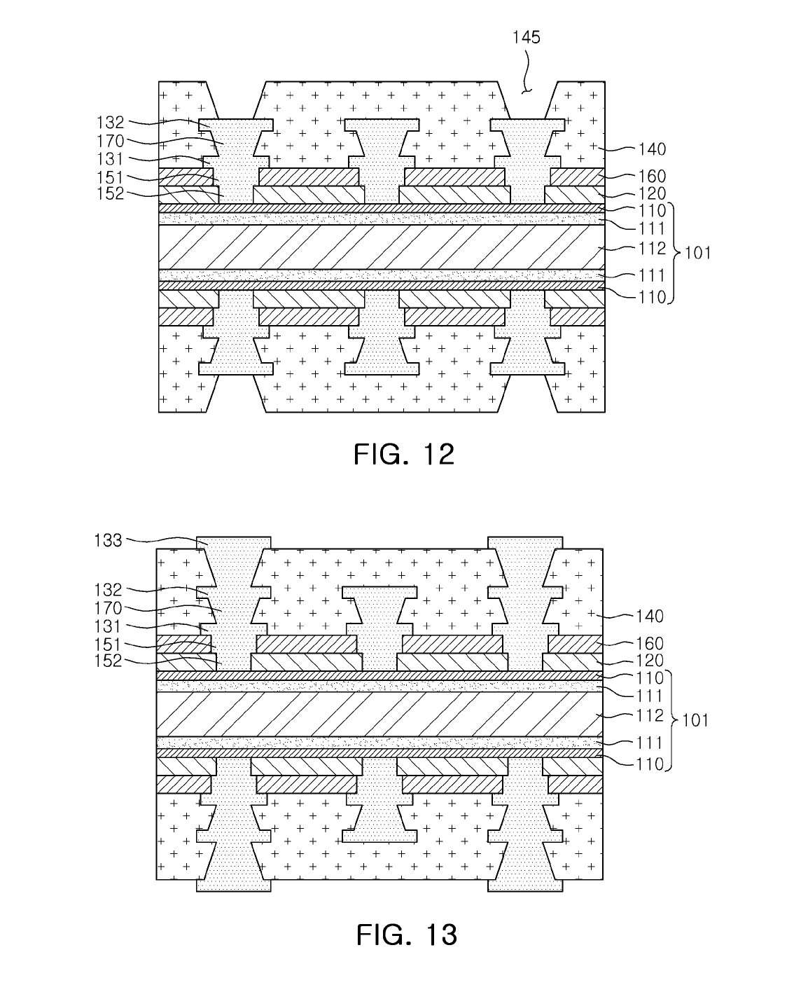

FIGS. 3 through 17 are views illustrating sequential processes in a method of manufacturing a PCB according to an exemplary embodiment of the present disclosure.

Referring to FIG. 3, first, a carrier substrate 101 is prepared.

The carrier substrate 101 may include a core 112, metal layers 111 formed on both surfaces of the core 112, and first metal layers 110 respectively formed on the metal layers 111.

The metal layers 111 and the first metal layers 110 may be formed of copper (Cu), but the present disclosure is not limited thereto. At least one facing surface of the metal layers 111 and the first metal layers 110 may be surface-treated so as to be easily separated.

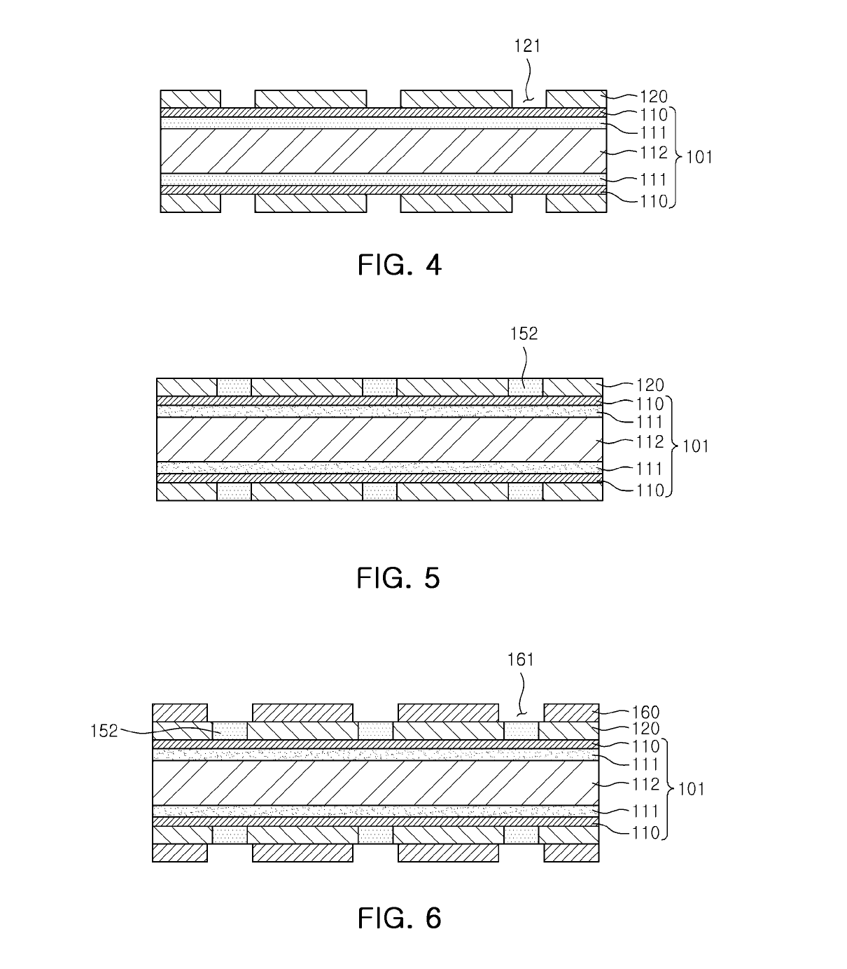

Referring to FIG. 4, a photoresist 120 having an opening 121 for forming a second metal post may be formed on the first metal layers 110.

The photoresist 120 may generally be formed of various types of photosensitive resist film, and dry film resist, or the like, may be used, but the present disclosure is not limited thereto.

Referring to FIG. 5, the opening 121 is filled with a metal to form a second metal post 152 by applying a process such as plating, or the like.

The metal post may be formed of any material as long as it may be used as a conductive metal without limitation. For example, copper (Cu) may be used.

Referring to FIG. 6, a solder resist 160 may be formed on the photoresist 120 such that the second metal post 152 is exposed.

The solder resist 160 formed to expose the second metal post 152 may have an opening 161 for forming a first metal post.

A width of the opening 161 for forming a first metal post may be equal to or greater than that of the second metal post 152.

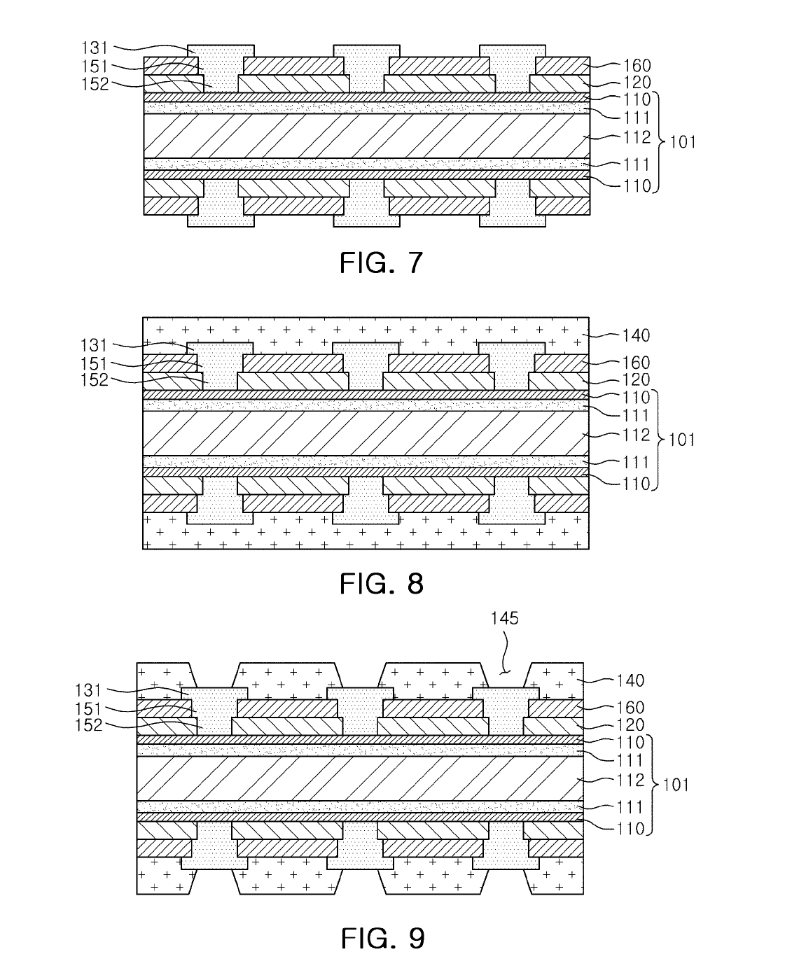

Referring to FIG. 7, a first circuit layer including a first metal post 151 and a first circuit pattern 131 may be formed on the second metal post 152.

In the metal post 150 formed thusly, a width of the second metal post 152 may be equal to or less than that of the first metal post 151.

The circuit layer may be formed of any material as long as it can be used as a conductive metal for a circuit without limitation. Typically, copper (Cu) is used in a PCB.

Referring to FIG. 8, an insulating layer 140 may be formed such that the first circuit pattern 131 is embedded.

A resin insulating layer may be used as the insulating layer 140. The resin insulating layer may be formed of a thermosetting resin such as an epoxy resin, a thermoplastic resin such as polyimide, or a material obtained by impregnating any of these resins with a reinforcing material such as glass fiber or an inorganic filler, for example, prepreg. Also, a thermosetting resin and/or a photocurable resin, or the like, may be used as a material of the resin insulating layer but the present disclosure is not limited thereto.

The first circuit pattern 131 may be embedded by the insulating layer 140 such that a level of the exposed upper surface thereof is equal to a level of the insulating layer 140.

Referring to FIG. 9, a via hole 145 may be formed in the insulating layer 140 such that the first circuit pattern 131 is exposed.

The via hole 145 may be formed using mechanical drill or laser drill, but the present disclosure is not limited thereto. Here, the laser drill may be a CO₂ laser or a YAG laser, but the present disclosure is not limited thereto.

In the drawing, the via hole 145 is illustrated as having a tapered shape having a diameter decreasing toward a lower surface, but the via electrode may be formed to have any shape known in the art, such as a tapered shape having a diameter increasing toward the lower surface, a cylindrical shape, or the like.

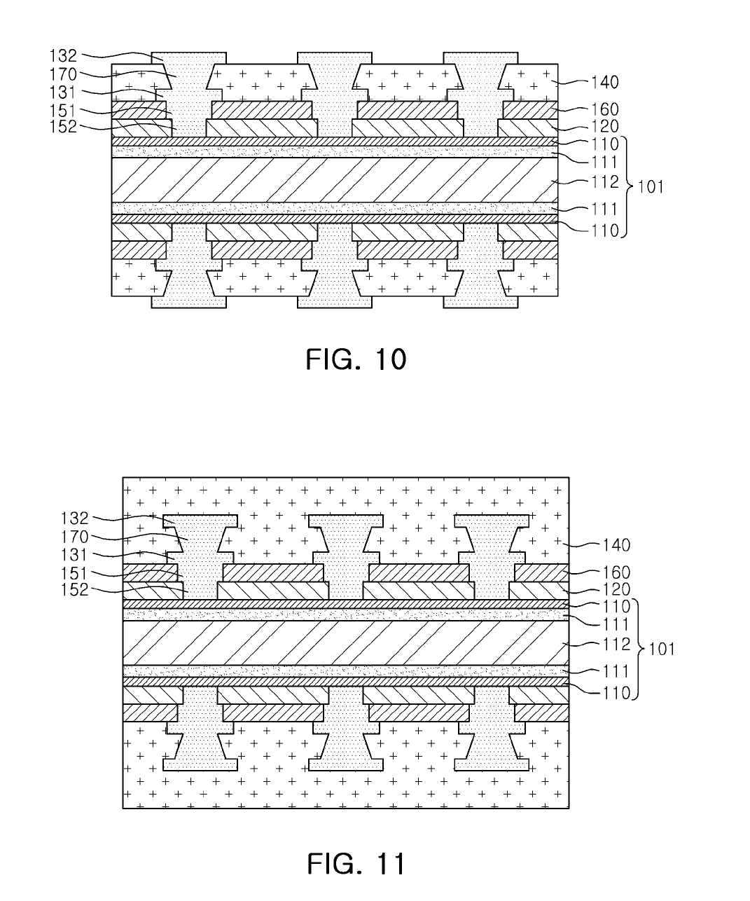

Referring to FIG. 10, the via hole 145 is filled to form a via electrode 170, and a second circuit layer including a second circuit pattern 132 electrically connected to the first circuit pattern 131 through the via electrode 170 may be formed.

A metal filling the via electrode 170 may be a material identical to that of the embedded first circuit pattern 131, and copper (Cu) is typically used therein. However, any material may be applied without limitation as long as it can be used as a conductive metal.

Referring to FIGS. 11 through 13, a build-up layer may be formed on the second circuit layer by repeated performing the process of forming the via electrode 170 and the second circuit pattern 132. The build-up layer may include a third circuit layer including a third circuit pattern 133 and a via electrode electrically connecting the second circuit pattern 132 and the third circuit pattern 133.

Here, in the drawing, the stacked build-up layer is illustrated as a dual-layer, but the build-up layer may also be formed as a triple layer or a quadruple layer, or may be formed within the scope utilized by a person skilled in the art.

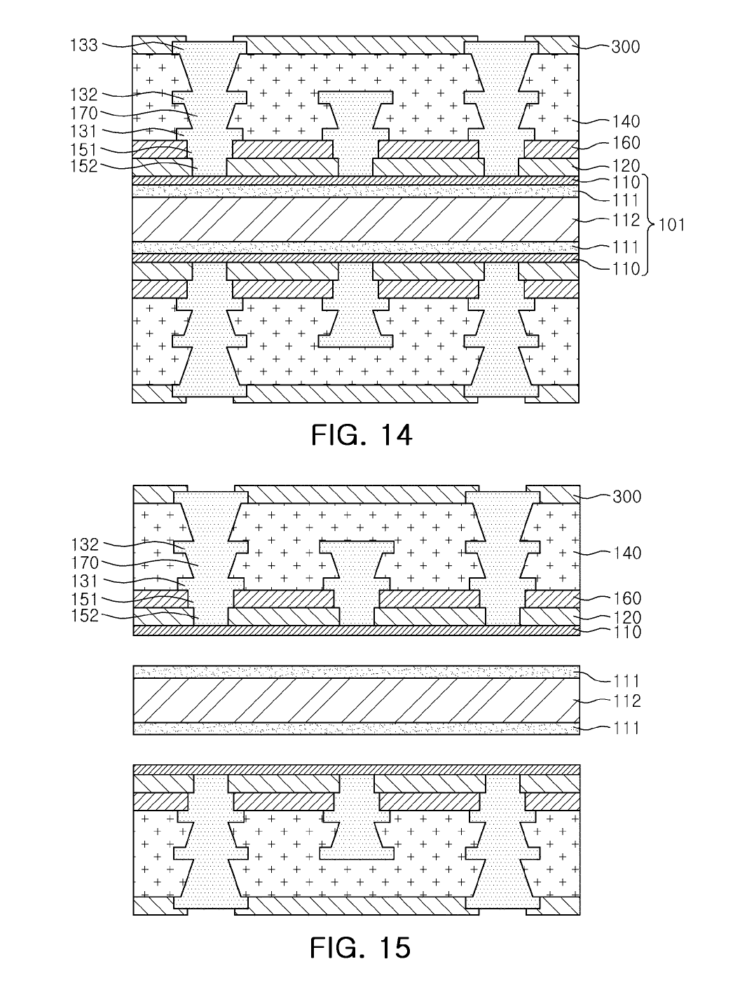

Referring to FIG. 14, solder resists 300 may be formed on both surfaces of the insulating layer 140 such that the circuit pattern for a connection pad of the outermost circuit layer is exposed.

Referring to FIG. 15, the metal layer 111 and the first metal layer 110 may be separated.

Here, the metal layer 111 and the first metal layer 110 may be separated using a blade, but the present disclosure is not limited thereto and any method known in the art may be used.

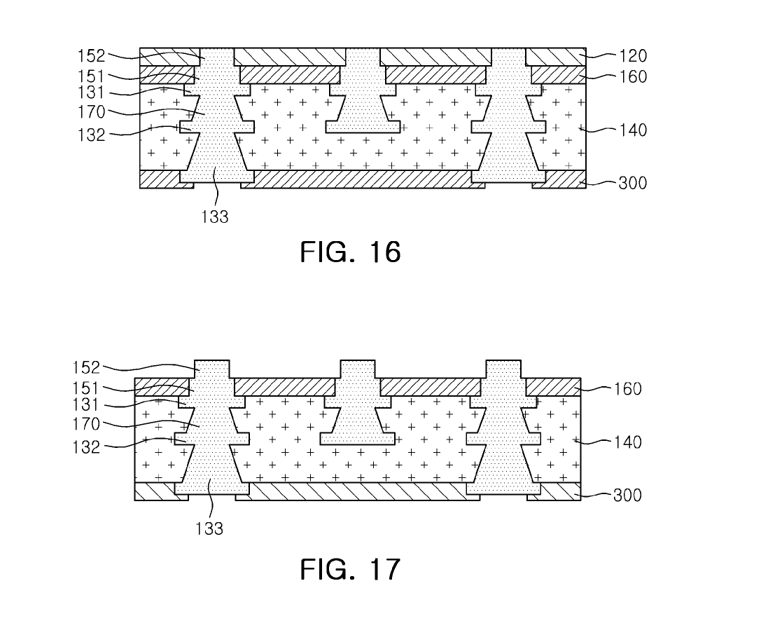

Referring to FIG. 16, the first metal layer 110 may be removed to expose the second metal post 152.

Here, the first metal layer 110 may be removed through an etching process, but the present disclosure is not limited thereto.

Referring to FIG. 17, the photoresist 120 may be removed.

As the photoresist 120 is removed, the second metal post 152 formed on the first metal post 151 may be protruded from the surface of the solder resist 160.

As set forth above, according to exemplary embodiments of the present disclosure, in the PCB, a fine pitch may be implemented by embedding circuit patterns and forming metal posts, and a thickness of the PCB may be reduced through a coreless structure.

While exemplary embodiments have been shown and described above, it will be apparent to those skilled in the art that modifications and variations could be made without departing from the spirit and scope of the present disclosure as defined by the appended claims.

What is claimed is:

1. A printed circuit board (PCB) comprising:
an insulating layer;
a first circuit layer including a first circuit pattern embedded in the first circuit layer, such that an upper surface of the first circuit pattern is exposed to a first surface of the insulating layer; and
a metal post formed on the first circuit pattern.

2. The printed circuit board of claim 1, wherein a level of an upper surface of the first circuit pattern is equal to a level of an upper surface of the insulating layer.

3. The printed circuit board of claim 1, further comprising:
a second circuit layer including a second circuit pattern formed on a second surface of the insulating layer; and
a via electrode formed in the insulating layer to electrically connect the first circuit pattern and the second circuit pattern.

4. The printed circuit board of claim 1, wherein the PCB has a coreless structure.

5. The printed circuit board of claim 1, further comprising a build-up layer stacked on the second surface of the insulating layer.

6. The printed circuit board of claim 1, further comprising a solder resist formed such that circuit patterns for a connection pad of the first circuit layer and the second circuit layer and the metal post are exposed.

7. The printed circuit board of claim 1, wherein the metal post includes a first metal post formed on the first circuit pattern and a second metal post formed on the first metal post and protruded from a surface of the solder resist.

8. The printed circuit board of claim 7, wherein a width of the second metal post is equal to or less than that of the first metal post.

9. The printed circuit board of claim 1, wherein the metal post is formed of copper (Cu).

10. A method of manufacturing a printed circuit board (PCB), the method comprising:
preparing a carrier substrate including a first metal layer formed on at least one surface thereof;
forming a photoresist having an opening for forming a second metal post on one surface of the first metal layer and filling the opening to form a second metal post;
forming a solder resist on the photoresist such that the second metal post is exposed;
forming a first circuit layer including a first metal post and a first circuit pattern on the second metal post; and
forming an insulating layer such that the first circuit pattern is embedded therein.

11. The method of claim 10, further comprising:
forming a via hole in the insulating layer such that the first circuit pattern is exposed; and
filling the via hole to form a via electrode and forming a second circuit layer including a second circuit pattern electrically connected to the first circuit pattern through the via electrode.

12. The method of claim 10, further comprising:
separating the first metal layer from the carrier substrate; and
removing the first metal layer and the photoresist.

13. The method of claim 10, wherein a level of an upper surface of the first circuit pattern is equal to a level of an upper surface of the insulating layer.

14. The method of claim 11, further comprising forming a build-up layer on the second circuit layer.

15. The method of claim 10, wherein a width of the second metal post is equal to or less than that of the first metal post.
